(19) United States
(12) Patent Application Publication
(10) Pub. No.: US 2024/0324297 A1
(43) Pub. Date: Sep. 26, 2024

(54) DISPLAY APPARATUS

(71) Applicant: Samsung Display Co., LTD., Yongin-si (KR)

(72) Inventors: Jiwon JUNG, Yongin-si (KR); Guanghai JIN, Yongin-si (KR)

(21) Appl. No.: 18/402,195

(22) Filed: Jan. 2, 2024

(30) Foreign Application Priority Data
Mar. 24, 2023 (KR) 10-2023-0039196
Jul. 26, 2023 (KR) 10-2023-0097800

(51) Int. Cl. H10K 59/122

(52) U.S. Cl. CPC H10K 59/122

(57) ABSTRACT

A display apparatus includes a substrate, on which a first display region is defined, and a first pixel unit disposed on the substrate in the first display region, where the first pixel unit includes a first pixel which emits light of a first color. The first pixel includes a pixel electrode, a bank layer disposed on the pixel electrode, where a pixel opening is defined in the bank layer to expose at least a portion of the pixel electrode, a plurality of insulating members disposed on the pixel electrode in the pixel opening, where the plurality of insulating members is arranged apart from each other, an intermediate layer disposed on the bank layer to cover the plurality of insulating members, and a common electrode disposed on the intermediate layer.

This application claims priority to Korean Patent Application Nos. 10-2023-0039196, filed on Mar. 24, 2023, and 10-2023-0097800, filed on Jul. 26, 2023, and all the benefits accruing therefrom under 35 U.S.C. § 119, the contents of which in their entirety are herein incorporated by reference.

### BACKGROUND

### 1. Field

One or more embodiments relate to an apparatus, and more particularly, to a display apparatus.

### 2. Description of the Related Art

In general, display apparatuses operate with light-emitting elements such as organic light-emitting diodes and thin-film transistors, which are formed on a substrate, and the light-emitting elements emit light.

In detail, each pixel of a display apparatus may include a light-emitting element such as an organic light-emitting diode in which an intermediate layer including an emission layer is arranged between a pixel electrode and an opposite electrode. Display apparatuses generally control whether each pixel emits light or the degree of light emission via a thin-film transistor electrically connected to a pixel electrode. Some layers included in an intermediate layer of a light-emitting element are commonly provided in a plurality of light-emitting elements.

### SUMMARY

One or more embodiments include a display apparatus with improved coherence. However, the embodiments are only examples, and the scope of the disclosure is not limited thereto.

According to one or more embodiments, a display apparatus includes a substrate, on which a first display region is defined, and a first pixel unit disposed on the substrate in the first display region, where the first pixel unit includes a first pixel which emits light of a first color. In such embodiments, the first pixel includes a pixel electrode, a bank layer disposed on the pixel electrode, where a pixel opening is defined in the bank layer to expose at least a portion of the pixel electrode, a plurality of insulating members disposed on the pixel electrode in the pixel opening, where the plurality of insulating members is arranged apart from each other, an intermediate layer disposed on the bank layer to cover the plurality of insulating members, and a common electrode disposed on the intermediate layer.

In an embodiment, each of the plurality of insulating members may be provided to have a longitudinal direction in a first direction.

In an embodiment, the plurality of insulating members may be apart from each other in a second direction crossing the first direction.

In an embodiment, in a plan view, the plurality of insulating members may have a stripe pattern.

In an embodiment, the plurality of insulating members may be apart from the bank layer.

In an embodiment, the first pixel unit may further include a second pixel which emits light of a second color and a third pixel which emits light of a third color, the first color may be red, the second color may be green, and the third color may be blue.

In an embodiment, the second pixel may be apart from the first pixel in a first direction, and the third pixel may be apart from the first pixel in a second direction crossing the first direction.

In an embodiment, a distance between the plurality of insulating members of the first pixel in the second direction may be less than a distance between the first pixel and the second pixel in the first direction.

In an embodiment, a distance between the plurality of insulating members of the first pixel in the second direction may be less than a distance between the first pixel and the third pixel in the second direction.

In an embodiment, a length of the first pixel in the first direction may be less than a length of the second pixel in the first direction, and the length of the second pixel in the first direction may be less than a length of the third pixel in the first direction.

According to one or more embodiments, a display apparatus includes a substrate, on which a first display region is defined, and a first pixel unit disposed on the substrate in the first display region, where the first pixel unit includes a first pixel which emits light of a first color. In such embodiments, the first pixel includes a pixel electrode, a bank layer disposed on the pixel electrode, where a pixel opening is defined in the bank layer to expose at least a portion of the pixel electrode, a plurality of insulating members disposed on the pixel electrode in the pixel opening, an intermediate layer disposed on the bank layer to cover the plurality of insulating members, and a common electrode disposed on the intermediate layer, and a plurality of first openings are respectively defined between adjacent insulating members among the plurality of insulating members.

In an embodiment, each of the plurality of first openings may be provided to have a longitudinal direction in a first direction.

In an embodiment, the plurality of first openings may be apart from each other in a second direction crossing the first direction.

In an embodiment, in a plan view, the plurality of insulating members may have a stripe pattern.

In an embodiment, the plurality of insulating members may be apart from the bank layer.

In an embodiment, the first pixel unit may further include a second pixel which emits light of a second color and a third pixel which emits light of a third color, the first color may be red, the second color may be green, and the third color may be blue.

In an embodiment, the second pixel may be apart from the first pixel in a first direction, and the third pixel may be apart from the first pixel in a second direction crossing the first direction.

In an embodiment, a distance between the adjacent insulating members among the plurality of insulating members of the first pixel in the second direction may be less than a distance between the first pixel and the second pixel in the first direction.

In an embodiment, a distance between the adjacent insulating members among the plurality of insulating members of the first pixel in the second direction may be less than a distance between the first pixel and the third pixel in the second direction.

In an embodiment, a length of the first pixel in the first direction may be less than a length of the second pixel in the first direction, and the length of the second pixel in the first direction may be less than a length of the third pixel in the first direction.

Features of embodiments other than those described above will become apparent from the following drawings, claims, and detailed description of the disclosure.

### BRIEF DESCRIPTION OF THE DRAWINGS

The above and other features of certain embodiments of the disclosure will be more apparent from the following description taken in conjunction with the accompanying drawings, in which:

FIG. 1 is a schematic plan view of a display apparatus according to an embodiment;

FIG. 2 is a schematic plan view of a first pixel unit;

FIG. 3 is a schematic cross-sectional view of a portion of a display apparatus according to an embodiment;

FIG. 4 is a schematic cross-sectional view of a portion of a display apparatus according to an embodiment; and

FIG. 5 is an equivalent circuit diagram of a pixel circuit electrically connected to a light-emitting diode included in one pixel.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the embodiments may be implemented in various forms, not by being limited to the embodiments presented below.

Hereinafter, embodiments will be described in detail with reference to the accompanying drawings, and in the description with reference to the drawings, the same or corresponding elements are indicated by the same reference numerals and any repetitive detailed descriptions thereof may be omitted or simplified.

In the following embodiment, it will be understood that although the terms “first,” “second,” etc. may be used herein to describe various elements, these elements should not be limited by these terms. These terms are only used to distinguish one element from another.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following embodiment, it will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following embodiments are not limited thereto.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

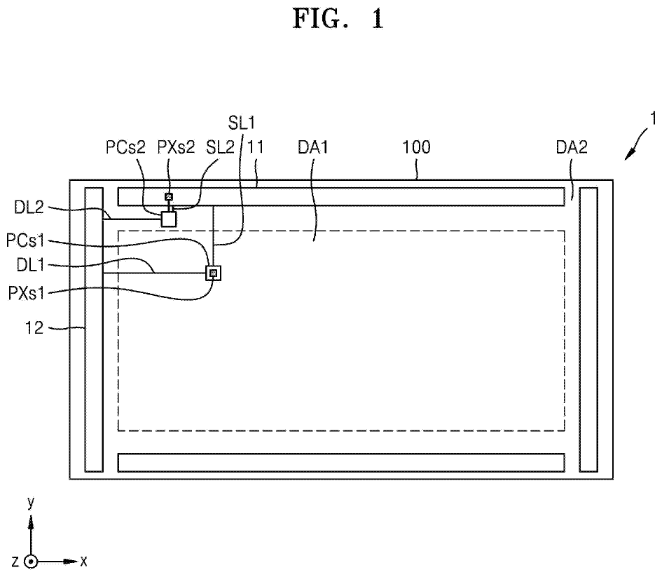

FIG. 1 is a schematic plan view of a display apparatus according to an embodiment. In detail, FIG. 1 is a schematic view of pixel units and a circuit driving unit of the display apparatus.

A display apparatus according to embodiments is an apparatus for displaying a moving image or a still image, and may be a display apparatus for extended reality (XR). For example, a display apparatus according to embodiments may be a display apparatus for virtual reality (VR), an augmented reality (AR), or mixed reality (MR).

A display apparatus according to embodiments is an apparatus for displaying a moving image or a still image, and may be used as display screens of various products such as televisions, laptops, monitors, billboards, or Internet of Things (IoTs) as well as portable electronic devices such as mobile phones, smart phones, tablet personal computers (tablet PCs), mobile communication terminals, electronic notebooks, e-books, portable multimedia players (PMPs), navigation devices, or ultra-mobile PCs (UMPCs). In addition, a display apparatus according to an embodiment may be used in wearable devices, such as smart watches, watch phones, glasses-type displays, and head mounted displays (HMDs). Furthermore, a display apparatus according to an embodiment may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment for a rear seat of vehicles.

In an embodiment, as shown in FIG. 1, a display apparatus 1 may include a first display region DA1 and a second display region DA2. In other words, a substrate 100 included in the display apparatus 1 may include the first display region DA1 and the second display region DA2 or the first display region DA1 and the second display region DA2 may be defined on the substrate 100. The second display region DA2 may be arranged to surround at least a portion of the first display region DA1 in a plan view (i.e., when viewed in a thickness direction of the substrate 100 or z-axis direction). The first display region DA1 may be entirely surrounded by the second display region DA2. The first display region DA1 may be provided to have a quadrangular shape. In detail, the length of the first display region DA1, which extends in a first direction (for example, y-axis direction), may be less than the length of the first display region DA1, which extends in a second direction (for example, x-axis direction). However, the disclosure is not limited thereto. Alternatively, the first display region DA1 may be provided to have a circular shape, a square shape, or an elliptical shape, and the length of the first display region DA1, which extends in the first direction (for example, y-axis direction), may be greater than the length of the first display region DA1, which extends in the second direction (for example, x-axis direction).

In an embodiment, a first pixel unit PXs1 may be arranged in the first display region DA1, and a second pixel unit PXs2 may be arranged in the second display region DA2. A first pixel circuit unit PCs1 for driving the first pixel unit PXs1 arranged in the first display region DA1 may be arranged in the first display region DA1. In detail, the first pixel circuit unit PCs1 may be arranged to overlap the first pixel unit PXs1. A second pixel circuit unit PCs2 for driving the second pixel unit PXs2 arranged in the second display region DA2 may be arranged in the second display region DA2. In other words, the second pixel circuit unit PCs2 for driving the second pixel unit PXs2 may be arranged not to overlap the second pixel unit PXs2. However, the disclosure is not limited thereto.

Not only the second pixel unit PXs2 and the second pixel circuit unit PCs2 but also circuit driving units 11 and 12 for driving the first pixel circuit unit PCs1 and the second pixel circuit unit PCs2 may be arranged in the second display region DA2. The circuit driving units 11 and 12 may include a scan driving unit 12 and a data driving unit 11. The data driving unit 11 may extend in the second direction (for example, x-axis direction) and be arranged in the second display region DA2. The scan driving unit 12 may extend in the first direction (for example, y-axis direction) and be arranged in the second display region DA2.

The data driving unit 11 may supply a data signal to the first pixel circuit unit PCs1 via a first data line DL1, and may supply a data signal to the second pixel circuit unit PCs2 via a second data line DL2. The scan driving unit 12 may supply a scan signal to the first pixel circuit unit PCs1 via a first scan line SL1, and may supply a scan signal to the second pixel circuit unit PCs2 via a second scan line SL2.

In an embodiment, the first pixel unit PXs1 and the first pixel circuit unit PCs1 arranged in the first display region DA1 may be arranged to overlap each other in the plan view (or in the thickness direction of the substrate 100). Because the data driving unit 11 and the scan driving unit 12 are arranged in the second display region DA2, in such an embodiment where the second pixel unit PXs2 is arranged to overlap the data driving unit 11 and the scan driving unit 12, the second pixel circuit unit PCs2 may be arranged not to overlap the second pixel unit PXs2. The second pixel unit PXs2 is also arranged in the second display region DA2 in which the data driving unit 11 and the scan driving unit 12 are arranged, and thus, the area of a region of the display apparatus 1, in which a screen is displayed, is widened, and resolution may increase.

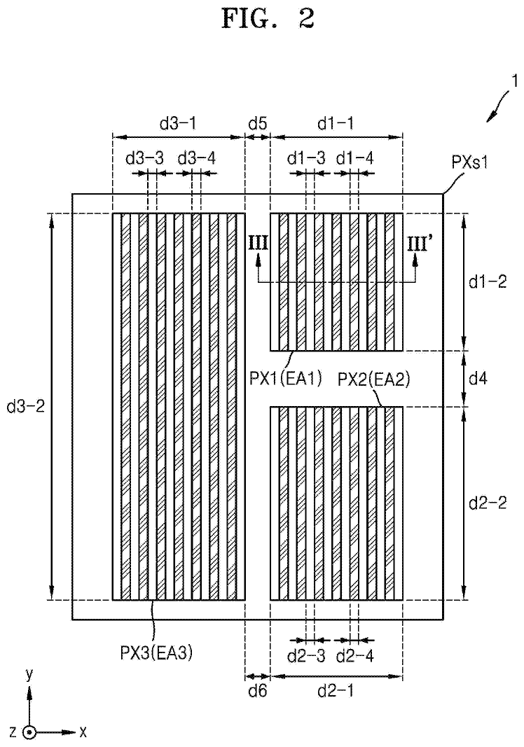

FIG. 2 is a schematic plan view of a first pixel unit.

Referring to FIG. 2, in an embodiment, the first pixel unit PXs1 may include a first pixel PX1, a second pixel PX2, and a third pixel PX3. The first pixel PX1 may emit light of a first color, the second pixel PX2 may emit light of a second color, and the third pixel PX3 may emit light of a third color. The first, second, and third color are different from each other. In an embodiment, for example, the light of the first color may be red light, the light of the second color may be green light, and the light of the third color may be blue light.

The first pixel PX1 may be a first emission region EA1 in which the light of the first color is emitted, and the second pixel PX2 may be a second emission region EA2 in which the light of the second color is emitted. In addition, the third pixel PX3 may be a third emission region EA3 in which the light of the third color is emitted. The sum of the areas of emission regions of the first pixel unit PXs1 may be the sum of the areas of the first emission region EA1 of the first pixel PX1, the second emission region EA2 of the second pixel PX2, and the third emission region EA3 of the third pixel PX3.

The second pixel PX2 may be apart from the first pixel PX1 in the first direction (for example, -y-axis direction), the third pixel PX3 may be apart from the first pixel PX1 in the second direction (for example, -x-axis direction), and the third pixel PX3 may be apart from the second pixel PX2 in the second direction (for example, -x-axis direction). The first direction (for example, y-axis direction) and the second direction (for example (for example, x-axis direction) may cross each other.

In the plan view, each of the first pixel PX1, the second pixel PX2, and the third pixel PX3 may have a quadrangular shape. A length d1-2 of the first pixel PX1 in the first direction (for example, y-axis direction) may be less than a length d2-2 of the second pixel PX2 in the first direction (for example, y-axis direction). The length d2-2 of the second pixel PX2 in the first direction (for example, y-axis direction) may be less than a length d3-2 of the third pixel PX3 in the first direction (for example, y-axis direction).

A length d1-1 of the first pixel PX1 in the second direction (for example, x-axis direction) may be equal to a length d2-1 of the second pixel PX2 in the second direction (for example, x-axis direction). In an embodiment, for example, the length d1-1 of the first pixel PX1 in the second direction (for example, x-axis direction), the length d2-1 of the second pixel PX2 in the second direction (for example, x-axis direction), and a length d3-1 of the third pixel PX3 in the second direction (for example, x-axis direction) may be equal to each other.

In an embodiment, the sum of the length d1-2 of the first pixel PX1 in the first direction (for example, y-axis direction), the length d2-2 of the second pixel PX2 in the first direction (for example, y-axis direction), and a distance d4 between the first pixel PX1 and the second pixel PX2 in the first direction (for example, y-axis direction)may be equal to the length d3-2 of the third pixel PX3 in the first direction (for example, y-axis direction). In addition, a distance d5 between the first pixel PX1 and the third pixel PX3 in the second direction (for example, x-axis direction) may be equal to a distance d6 between the second pixel PX2 and the third pixel PX3 in the second direction (for example, x-axis direction).

In the structure described above, in the plan view, the first emission region EA1, the second emission region EA2, and the third emission region EA3 may increase in area in this stated order. However, this is merely an example, and the shapes and sizes of the first pixel PX1, the second pixel PX2, and the third pixel PX3 may vary depending on the types of the first color, the second color, and the third color.

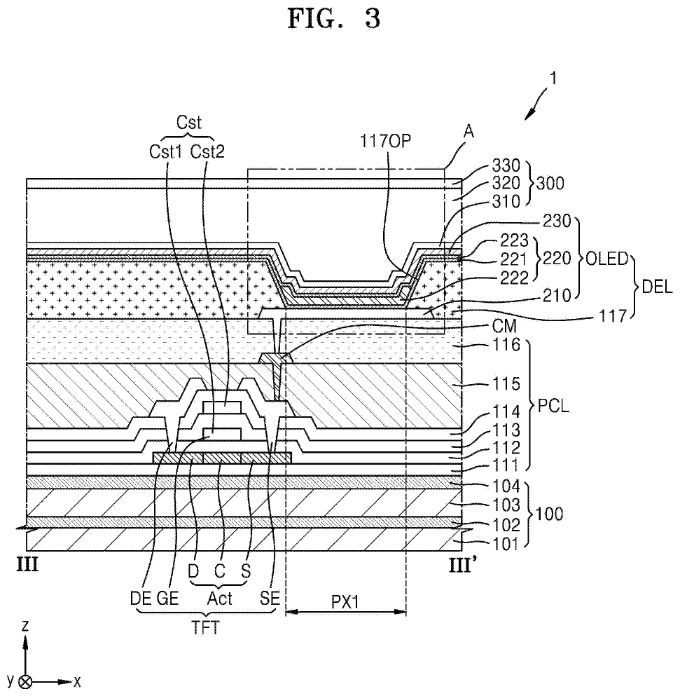

FIG. 3 is a schematic cross-sectional view of a portion of a display apparatus according to an embodiment. FIG. 3 may correspond to a cross-section of the display apparatus 1 taken along line III-IlI′ of FIG. 2.

Referring to FIG. 3, an embodiment of the display apparatus 1 may include a stacked structure of the substrate 100, a pixel circuit layer PCL, a display element layer DEL, and an encapsulation layer 300.

The substrate 100 may have a multilayer structure including a base layer including polymer resin and an inorganic layer. In an embodiment, for example, the substrate 100 may include a base layer including polymer resin and a barrier layer that is an inorganic insulating layer. In an embodiment, for example, the substrate 100 may include a first base layer 101, a first barrier layer 102, a second base layer 103, and a second barrier layer 104, which are sequentially stacked. Each of the first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC), or/and cellulose acetate propionate (CAP). The first barrier layer 102 and the second barrier layer 104 may include an inorganic insulating material, such as silicon oxide, silicon oxynitride, and/or silicon nitride. The substrate 100 may have flexibility.

The pixel circuit layer PCL is disposed on the substrate 100. FIG. 3 illustrates an embodiment where the pixel circuit layer PCL includes a thin-film transistor TFT, and further includes a buffer layer 111, a first gate insulating layer 112, a second gate insulating layer 113, an interlayer insulating layer 114, a first planarization insulating layer 115, and a second planarization insulating layer 116, which are disposed under or/and above constituent elements of the thin-film transistor TFT.

The buffer layer 111 may reduce or block infiltration of foreign substances, moisture, or external air from under the substrate 100, and may provide a flat surface on the substrate 100. The buffer layer 111 may include an inorganic insulating material, such as silicon oxide, silicon oxynitride, or silicon nitride, and may have a single-layered or multilayer structure, each layer therein including at least one selected from the above-described materials.

The thin-film transistor TFT on the buffer layer 111 may include a semiconductor layer Act, and the semiconductor layer Act may include polysilicon (poly-Si). Alternatively, the semiconductor layer Act may include amorphous silicon (a-Si), an oxide semiconductor, or an organic semiconductor. The semiconductor layer Act may include a channel region C, and a drain region D and a source region S respectively arranged at opposing sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti), and may have a single-layered or multilayer structure, each layer therein including at least one selected from the above-described materials.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂).

The second gate insulating layer 113 may be provided to cover the gate electrode GE. The second gate insulating layer 113, similar to the first gate insulating layer 112, may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include ZnO and/or ZnO₂.

An upper electrode Cst2 of a storage capacitor Cst may be disposed on the second gate insulating layer 113. The upper electrode Cst2 may overlap the gate electrode GE thereunder. In an embodiment, the gate electrode GE and the upper electrode Cst2 overlapping each other with the second gate insulating layer 113 therebetween may form the storage capacitor Cst. In such an embodiment, the gate electrode GE may function as a lower electrode Cst1 of the storage capacitor Cst.

As such, the storage capacitor Cst and the thin-film transistor TFT may overlap each other. In some embodiments, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single-layered or multilayer structure, each layer therein including at least one selected from the above-described materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). ZnOₓ may include zinc oxide (ZnO) and/or zinc peroxide (ZnO₂). The interlayer insulating layer 114 may have a single-layered or multilayer structure, each layer therein including at least one selected from the above-described inorganic insulating materials.

A drain electrode DE and a source electrode SE may each be disposed on the interlayer insulating layer 114. The drain electrode DE and the source electrode SE may be respectively connected to the drain region D and the source region S through contact holes defined or formed in the insulating layers thereunder. Each of the drain electrode DE and the source electrode SE may include a material exhibiting high conductivity. The drain electrode DE and the source electrode SE may include a conductive material including molybdenum (Mo), aluminum (AI), copper (Cu), or titanium (Ti), and may have a single-layered or multilayer structure, each layer therein including at least one selected from the above-described materials. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material, such as a general-purpose polymer such as polymethylmethacrylate (PMMA) or polystyrene (PS), a polymer derivative having a phenolic group, an acrylic polymer, an imide-based polymer, an aryl ether-based polymers, an amide-based polymer, a fluorine-based polymer, a p-xylene-based polymer, a vinyl alcohol-based polymer, or a blend thereof.

The second planarization insulating layer 116 may be disposed on the first planarization insulating layer 115. The second planarization insulating layer 116 may include a material the same as that of the first planarization insulating layer 115, and may include an organic insulating material, such as a general-purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the above-described structure. The display element layer DEL may include an organic light-emitting diode OLED as a display element (that is, a light-emitting element), and the organic light-emitting diode OLED may include a structure of a stack of a pixel electrode 210, an intermediate layer 220, and a common electrode 230. The organic light-emitting diode OLED may emit, for example, red, green, or blue light, or red, green, blue, or white light. The organic light-emitting diode OLED may emit light via an emission region and define the emission region corresponding to the first pixel PX1.

The pixel electrode 210 of the organic light-emitting diode OLED may be electrically connected with the thin-film transistor TFT via contact holes defined or formed in the second planarization insulating layer 116 and the first planarization insulating layer 115 and a contact metal CM disposed on the first planarization insulating layer 115.

In an embodiment, the pixel electrode 210 may include a conductive oxide such as indium tin oxide (ITO), indium zinc oxide (IZO), zinc oxide (ZnO), indium oxide (In203), indium gallium oxide (IGO), or aluminum zinc oxide (AZO). In an alternative embodiment, the pixel electrode 210 may include a reflective film including silver (Ag), magnesium (Mg), aluminum (AI), platinum (Pt), palladium (Pd), gold (Au), nickel (Ni), neodymium (Nd), iridium (Ir), chromium (Cr), or a compound thereof. In another alternative embodiment, the pixel electrode 210 may further include a film including ITO, IZO, ZnO, or In203 above/under the above-described reflective film.

A bank layer 117 provided with a pixel opening 117OP defined therein to expose a center portion of the pixel electrode 210 is disposed on the pixel electrode 210. The bank layer 117 may include an organic insulating material and/or an inorganic insulating material. The pixel opening 117OP may define an emission region of light emitted from the organic light-emitting diode OLED. In an embodiment, for example, the size/width of the pixel opening 117OP may correspond to the size/width of the emission region. Therefore, the size and/or width of the first pixel PX1 may depend on (or be determined based on) the size and/or width of the pixel opening 117OP of the bank layer 117.

The intermediate layer 220 may include an emission layer 222 formed to correspond to the pixel electrode 210. The emission layer 222 may include a polymer or low molecular weight organic material that emits light of a certain color. Alternatively, the emission layer 222 may include an inorganic light-emitting material or quantum dots.

In an embodiment, the intermediate layer 220 may include a first functional layer 221 and a second functional layer 223 which are respectively disposed below and above the emission layer 222. The first functional layer 221 may include, for example, a hole transport layer (HTL), or a HTL and a hole injection layer (HIL). The second functional layer 223 that is disposed above the emission layer 222 may include an electron transport layer (ETL) and/or an electron injection layer (EIL). The first functional layer 221 and/or the second functional layer 223, like the common electrode 230 described below, may be a common layer that is formed to entirely cover the substrate 100.

The common electrode 230 is disposed on the pixel electrode 210 and may overlap the pixel electrode 210. The common electrode 230 may include a conductive material having a low work function. In an embodiment, for example, the common electrode 230 may include a (semi-)transparent layer including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. Alternatively, the common electrode 230 may further include a layer including ITO, IZO, ZnO, or In203 on the (semi-)transparent layer including the above-described material. The common electrode 230 may be commonly provided over (i.e., integrally formed to entirely cover) the substrate 100.

The encapsulation layer 300 is disposed on the display element layer DEL and may cover the display element layer DEL. The encapsulation layer 300 includes at least one an inorganic encapsulation layer and at least one organic encapsulation layer. In an embodiment, as shown in FIG. 3, the encapsulation layer 300 includes a first inorganic encapsulation layer 310, an organic encapsulation layer 320, and a second inorganic encapsulation layer 330, which are sequentially stacked.

Each of the first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, or polyethylene. In an embodiment, the organic encapsulation layer 320 may include acrylate. The organic encapsulation layer 320 may be formed by curing a monomer or applying a polymer. The organic encapsulation layer 320 may have transparency.

In an embodiment, although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce the reflectance of light (external light) incident on the display apparatus, and/or may improve the color purity of light emitted from the display apparatus. In an embodiment, the optical functional layer may include a retarder and/or a polarizer. The retarder may be of a film type or a liquid crystal coating type, and may include a λ/2 retarder and/or a λ/4 retarder. The polarizer may also be of a film type or a liquid crystal coating type. The film type may include a stretchable synthetic resin film, and the liquid crystal coating type may include liquid crystals arranged in a certain array. Each of the retarder and the polarizer may further include a protective film.

In such an embodiment, an adhesive member (not shown) may be arranged between the touch electrode layer and the optical functional layer. The adhesive member may be any general member generally known in the related art without limitation. The adhesive member may be a pressure sensitive adhesive (PSA).

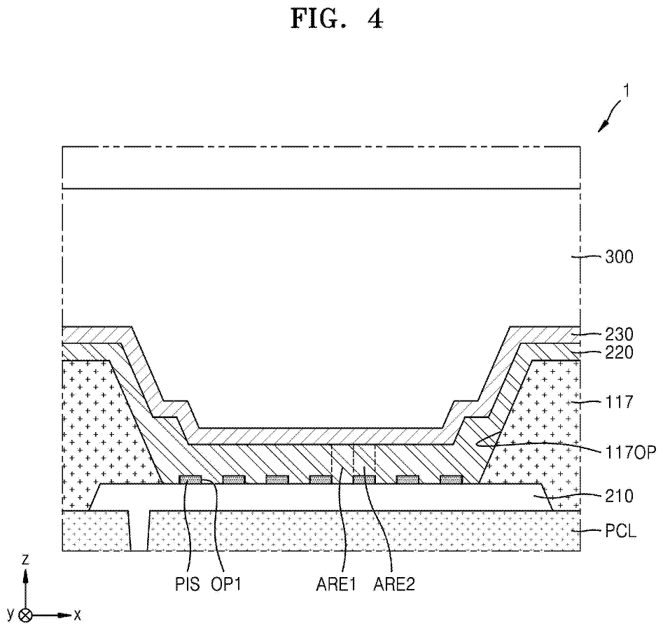

FIG. 4 is a schematic cross-sectional view of a portion of a display apparatus according to an embodiment. In detail, FIG. 4 is an enlarged view of portion A of FIG. 3.

Referring to FIGS. 2 to 4, in an embodiment, the first pixel PX1 may include the pixel electrode 210, the bank layer 117, a plurality of insulating members PIS, the intermediate layer 220, and the common electrode 230.

The same reference numerals in FIGS. 2 to 4 denote the same members, and thus, any repeated detailed descriptions thereof will be omitted.

In an embodiment, the bank layer 117 is disposed on the pixel electrode 210, and the pixel opening 117OP that exposes at least a portion of the pixel electrode 210 may be arranged in the bank layer 117. The bank layer 117 may be in contact with the pixel electrode 210 and the pixel circuit layer PCL. The pixel opening 117OP may be arranged in the center of the pixel electrode 210. As shown in FIG. 4, in a cross-section, an inner circumferential surface of the bank layer 117, which defines the pixel opening 117OP, may be inclined with respect to an upper surface of the pixel electrode 210.

The plurality of insulating members PIS may be disposed on the pixel electrode 210 to be accommodated in the pixel opening 117OP. The plurality of insulating members PIS may be disposed in the pixel opening 117OP in the plan view. The plurality of insulating members PIS may be arranged to be apart from each other. In an embodiment, as shown in FIG. 2, in the plan view, each of the plurality of insulating members PIS may be provided to have a longitudinal direction (or extend) in the first direction (for example, y-axis direction). The length of each of the plurality of insulating members PIS in the first direction (for example, y-axis direction) may be equal to the length of first emission region EA1 in the first direction (for example, y-axis direction). The plurality of insulating members PIS may be apart from each other in the second direction (for example, x-axis direction). The plurality of insulating members PIS may be apart from the bank layer 117.

A plurality of first openings OP1 may be respectively defined between adjacent insulating members PIS among the plurality of insulating members PIS. As shown in FIG. 2, in the plan view, each the plurality of first openings OP1 may be provided to have a longitudinal direction in the first direction (for example, y-axis direction). The length of each of the plurality of first openings OP1 in the first direction (for example, y-axis direction) may be equal to the length of the first emission region EA1 in the first direction (for example, y-axis direction). The plurality of first openings OP1 may be apart from each other in the second direction (for example, x-axis direction). Two of the plurality of first openings OP1 may be in contact with the bank layer 117. In the structure described above, the plurality of insulating members PIS may have a stripe pattern.

FIGS. 2 and 4 illustrate an embodiment where distances between the plurality of insulating members PIS are equal to each other, but this is merely an example, and the arrangement of the plurality of insulating members PIS is not limited thereto. In addition, FIG. 4 illustrates an embodiment where a cross-section of each of the plurality of insulating members PIS is quadrangular, but this is merely an example, and the shape of the cross-section of each of the plurality of insulating members PIS is not limited thereto.

The plurality of insulating members PIS may include an inorganic insulating material such as silicon oxide (SiOx), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ).

The intermediate layer 220 may be disposed on the bank layer 117 to cover the plurality of insulating members PIS. The intermediate layer 220 may be in contact with the plurality of insulating members PIS, the pixel electrode 210, and the bank layer 117. The plurality of insulating members PIS may be sealed by the intermediate layer 220 and the pixel electrode 210. The common electrode 230 may be disposed on the intermediate layer 220, and the encapsulation layer 300 may be disposed on the common electrode 230.

In an embodiment, as shown in FIG. 4, in a cross-section, a region of the intermediate layer 220, which overlaps the plurality of first openings OP1 in the z-axis direction (or in the plan view), is referred to as a first region ARE1, and a region of the intermediate layer 220, which overlaps the plurality of insulating members PIS in the z-axis direction, is referred to as a second region ARE2. In such an embodiment, the first region ARE1 may not overlap the plurality of insulating members PIS, and the second region ARE2 may not overlap the plurality of first openings OP1.

In the first region ARE1, the intermediate layer 220 may be electrically connected with the pixel electrode 210. Therefore, in the first region ARE1, the intermediate layer 220 may emit light according to interaction with the pixel electrode 210 and the common electrode 230.

However, in the second region ARE2, the intermediate layer 220 may not be electrically connected with the pixel electrode 210. Because the plurality of insulating members PIS are arranged between the intermediate layer 220 and the pixel electrode 210 in the second region ARE2, current may not flow between the intermediate layer 220 and the pixel electrode 210. Therefore, the intermediate layer 220 may not emit light in the second region ARE2.

In an embodiment of the display apparatus 1 for extended reality (XR), it may be desired as the intermediate layer 220 emits light having high coherence. In such an embodiment, it may be desired as the coherence length of light emitted from the intermediate layer 220 increases.

The coherence length may be expressed as λ0²/nΔλ. In this regard, Δ0 may refer to a center wavelength of a light source, Δλ may refer to the width of a spectral line of the light source, and n may refer to a refractive index of a medium. In an embodiment of the disclosure, as an emission region of the intermediate layer 220 is divided into a plurality of first regions ARE1, the full width at half maximum (FWHM) decreases, and thus, Δλ may decrease. Therefore, in such an embodiment, as the coherence length increases, coherence may increase.

In FIGS. 3 and 4, only the first pixel PX1 is illustrated as an example, but as shown in FIG. 1, like the first pixel PX1, each of the second pixel PX2 and the third pixel PX3 may also include a plurality of insulating members. In other words, in the second pixel PX2, the second color may be divided into a plurality of regions and emitted, and in the third pixel PX3, the third color may be divided into a plurality of regions and emitted. Therefore, coherence of light emitted from the second pixel PX2 may increase. In addition, coherence of light emitted from the third pixel PX3 may increase.

Referring to FIGS. 2 and 4, in an embodiment, a distance d1-3 between the plurality of insulating members PIS arranged in the first pixel PX1, a distance d2-3 between a plurality of insulating members arranged in the second pixel PX2, and a distance d3-3 between a plurality of insulating members arranged in the third pixel PX3 may be equal to each other. In such an embodiment, a width d1-4 of each of the plurality of insulating members PIS arranged in the first pixel PX1, a width d2-4 of each of the plurality of insulating members arranged in the second pixel PX2, and a width d3-4 of the plurality of insulating members arranged in the third pixel PX3 may be equal to each other.

Each of the distance d4 between the first pixel PX1 and the second pixel PX2, the distance d5 between the first pixel PX1 and the third pixel PX3, and the distance d6 between the second pixel PX2 and the third pixel PX3 may be greater than each of the distance d1-3 between the plurality of insulating members PIS arranged in the first pixel PX1, the distance d2-3 between the plurality of insulating members arranged in the second pixel PX2, and the distance d3-3 between the plurality of insulating members arranged in the third pixel PX3. Therefore, mixing of the first color, the second color, and the third color with each other may be substantially reduced or effectively prevented.

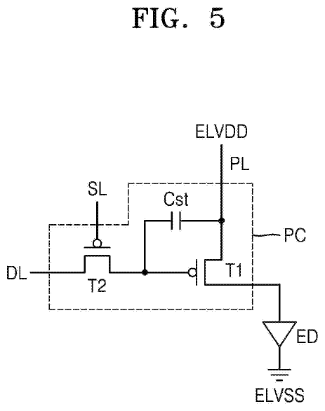

FIG. 5 is an equivalent circuit diagram of a pixel circuit electrically connected to a light-emitting diode included in one pixel.

Referring to FIG. 5, an embodiment of a pixel circuit PC may include a first transistor T1, a second transistor T2, and the storage capacitor Cst. The second transistor T2 is a switching transistor, and may be connected to a scan line SL and a data line DL and may be turned on by a switching signal input from the scan line SL to transmit a data signal input from the data line DL to the first transistor T1. The storage capacitor Cst may have one end electrically connected to the second transistor T2 and the other end electrically connected to a driving voltage line PL, and may store a voltage corresponding to a difference between a voltage received from the second transistor T2 and a driving power voltage ELVDD supplied to the driving voltage line PL.

The first transistor T1 is a driving transistor, and may be connected to the driving voltage line PL and the storage capacitor Cst and may be configured to control the magnitude a driving current flowing from the driving voltage line PL to a light-emitting diode ED, based on a voltage value stored in the storage capacitor Cst. The light-emitting diode ED may emit light having a certain luminance by the driving current. An opposite electrode of the light-emitting diode ED may receive an electrode power voltage ELVSS.

FIG. 5 illustrates an embodiment where the pixel circuit PC includes two transistors and one storage capacitor, but the disclosure is not limited thereto. For example, the number of transistors or the number of storage capacitors may vary according to the design of the pixel circuit PC.

According to an embodiment, a display apparatus with improved coherence may be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate on which a first display region is defined; and
a first pixel unit disposed on the substrate in the first display region, wherein the first pixel unit comprises a first pixel which emits light of a first color,
wherein the first pixel comprises:
a pixel electrode;
a bank layer disposed on the pixel electrode, wherein a pixel opening is defined in the bank layer to expose at least a portion of the pixel electrode;
a plurality of insulating members disposed on the pixel electrode in the pixel opening, wherein the plurality of insulating members is arranged apart from each other;
an intermediate layer disposed on the bank layer to cover the plurality of insulating members; and
a common electrode disposed on the intermediate layer.

2. The display apparatus of claim 1, wherein each of the plurality of insulating members is provided to have a longitudinal direction in a first direction.

3. The display apparatus of claim 2, wherein the plurality of insulating members are apart from each other in a second direction crossing the first direction.

4. The display apparatus of claim 3, wherein, in a plan view, the plurality of insulating members have a stripe pattern.

5. The display apparatus of claim 1, wherein the plurality of insulating members are apart from the bank layer.

6. The display apparatus of claim 1, wherein the first pixel unit further comprises:
a second pixel which emits light of a second color; and
a third pixel which emits light of a third color, and
the first color is red, the second color is green, and the third color is blue.

7. The display apparatus of claim 6, wherein the second pixel is apart from the first pixel in a first direction, and
the third pixel is apart from the first pixel in a second direction crossing the first direction.

8. The display apparatus of claim 7, wherein a distance between the plurality of insulating members of the first pixel in the second direction is less than a distance between the first pixel and the second pixel in the first direction.

9. The display apparatus of claim 7, wherein a distance between the plurality of insulating members of the first pixel in the second direction is less than a distance between the first pixel and the third pixel in the second direction.

10. The display apparatus of claim 7, wherein a length of the first pixel in the first direction is less than a length of the second pixel in the first direction, and
the length of the second pixel in the first direction is less than a length of the third pixel in the first direction.

11. A display apparatus comprising:
a substrate on which a first display region is defined; and
a first pixel unit disposed on the substrate in the first display region, and comprising a first pixel which emits light of a first color,
wherein the first pixel comprises:
a pixel electrode;
a bank layer disposed on the pixel electrode, wherein a pixel opening is defined in the bank layer to expose at least a portion of the pixel electrode;
a plurality of insulating members disposed on the pixel electrode in the pixel opening;
an intermediate layer disposed on the bank layer to cover the plurality of insulating members; and
a common electrode disposed on the intermediate layer, and
a plurality of first openings are respectively defined between adjacent insulating members among the plurality of insulating members.

12. The display apparatus of claim 11, wherein each of the plurality of first openings is provided to have a longitudinal direction in a first direction.

13. The display apparatus of claim 12, wherein the plurality of first openings are apart from each other in a second direction crossing the first direction.

14. The display apparatus of claim 13, wherein, in a plan view, the plurality of insulating members have a stripe pattern.

15. The display apparatus of claim 11, wherein the plurality of insulating members are apart from the bank layer.

16. The display apparatus of claim 11, wherein the first pixel unit further comprises:
a second pixel which emits light of a second color; and
a third pixel which emits light of a third color, and
the first color is red, the second color is green, and the third color is blue.

17. The display apparatus of claim 16, wherein the second pixel is apart from the first pixel in a first direction, and
the third pixel is apart from the first pixel in a second direction crossing the first direction.

18. The display apparatus of claim 17, wherein a distance between the adjacent insulating members among the plurality of insulating members of the first pixel in the second direction is less than a distance between the first pixel and the second pixel in the first direction.

19. The display apparatus of claim 17, wherein a distance between the adjacent insulating members among the plurality of insulating members of the first pixel in the second direction is less than a distance between the first pixel and the third pixel in the second direction.

20. The display apparatus of claim 17, wherein a length of the first pixel in the first direction is less than a length of the second pixel in the first direction, and
the length of the second pixel in the first direction is less than a length of the third pixel in the first direction.
